(19) United States
(12) Patent Application Publication
(10) Pub. No.: US 2026/0142430 A1
(43) Pub. Date: May 21, 2026

(54) VARIABLE LENGTH BUSBAR MODULE FOR ELECTRIC VEHICLE

(71) Applicant: Hyundai Kefico Corporation, Gunpo (KR)

(72) Inventors: Ki Won Sung, Gunpo (KR); Seung Hyuk Oh, Gunpo (KR); Jin Kyu Park, Gunpo (KR)

(21) Appl. No.: 19/396,112

(22) Filed: Nov. 20, 2025

(30) Foreign Application Priority Data
Nov. 20, 2024 (KR) 10-2024-0166239

(51) Int. Cl. H01R 25/16; H01R 12/70; H01R 12/73; H01R 13/41; H01R 13/50; H01R 13/642; H01R 13/6587; H01R 31/06

(52) U.S. Cl. CPC H01R 25/162; H01R 12/7047; H01R 12/732; H01R 13/41; H01R 13/50; H01R 13/642; H01R 13/6587; H01R 31/06; H01R 2201/26

(57) ABSTRACT

A variable length busbar module for a vehicle includes: a first busbar assembly coupled to a first substrate, a second busbar assembly coupled to a second substrate, and a busbar intermediate assembly for connecting the first busbar assembly and the second busbar assembly to each other, where the busbar intermediate assembly is configured to be provided in various lengths. The variable length busbar module is capable of achieving product standardization by changing only the length of the busbar intermediate assembly when busbars of different lengths are required due to package design. The first busbar assembly and the second busbar assembly may be used interchangeably.

### CROSS REFERENCE TO RELATED APPLICATION

The present application claims under 35 U.S.C. § 119(a) the benefit of Korean Patent Application No. 10-2024-0166239 filed Nov. 20, 2024, the entire contents of which are incorporated by reference herein.

### BACKGROUND

### (a) Technical Field

The present disclosure relates to a variable length busbar module used for electrical connection between printed circuit boards (PCBs), more particularly, to a variable length busbar module used for electrical connection between printed circuit boards (PCBs), which is capable of achieving product standardization by changing only the length of a busbar intermediate assembly when busbars of different lengths are required due to package design.

### (b) Description of the Related Art

A busbar is a metallic strip or bar used for efficient transmission of electrical energy. Typically, a busbar is mainly made of copper and serves to transmit or distribute electric current within an electrical system, and thus may replace certain existing cables.

Busbars are essential components of electrical switches, distribution boards, voltage converters, battery parts, etc. Due to rapid expansion of electric vehicles in recent years, busbars are also being used as essential components in a power conversion device including an integrated charging control unit (ICCU), an on-board charger (OBC), a DC-DC converter, and the like, which are installed in an electric vehicle.

Busbars typically are used to make connections between multiple points requiring electrical connection while maximally reducing power loss, and should be configured to enhance the stability of an electrical system.

FIG. 1 (RELATED ART) is a perspective view illustrating a power conversion device installed on an electric vehicle, showing the arrangement of a plurality of PCB substrates inside the power conversion device. In particular, this perspective view shows that a busbar 10 is mounted as a means for electrical connection between a first substrate 20 and a second substrate 30, which are arranged at heights different from each other.

As shown in FIG. 1, the busbar 10 may constitute various busbars of different lengths depending on the arrangement of the first substrate 20 and the second substrate 30, and new busbars of various lengths may be manufactured each time when an electric vehicle's specifications such as a power conversion device of the electric vehicle being developed are changed, thereby causing problems that require mold costs for new busbar production, performance analysis and certification of the newly manufactured busbars, production schedules, etc.

For example, Korean Patent No. 10-1652495 discloses a busbar whose length is adjustable. The busbar has a structure that includes at least one connecting wire for connecting a first busbar and a second busbar, wherein the first busbar and the second busbar are composed of a body including a wire receiving part and a fixing part that pressurizes and fixes the connecting wire, and are provided with a structure for adjusting the length of the connecting wire to be inserted.

The busbar of the above-described patent has the advantage in terms of having a structure with variable length, but has the limitation of being structurally weak for use in automobiles that are subject to the vibrations and impacts of various frequency bands and intensities due to the structure of the fixing part configured to connect a side surface of a wire with a screw.

Therefore, it would be desirable to develop a busbar capable of transmitting stable power while overcoming the problems of conventional busbars.

### SUMMARY

An objective of the present disclosure is to provide a variable length busbar module, e.g., for use in an electric vehicle, which is capable of achieving product standardization by changing only the length of a busbar intermediate assembly when busbars of different lengths are required due to package design.

According to the present disclosure, a variable length busbar module for a vehicle includes: a first busbar assembly coupled to a first substrate; a second busbar assembly coupled to a second substrate; and a busbar intermediate assembly for connecting the first busbar assembly and the second busbar assembly to each other, wherein the busbar intermediate assembly is configured to be provided in various lengths.

In addition, the first busbar assembly and the second busbar assembly are configured to be used interchangeably.

According to one aspect of the present disclosure for solving the problems, there is provided a variable length busbar module, including: a first busbar assembly coupled to a first substrate; a second busbar assembly coupled to a second substrate; and a busbar intermediate assembly for connecting the first busbar assembly and the second busbar assembly to each other, wherein the first busbar assembly and the second busbar assembly may be used interchangeably (e.g., in common), and the busbar intermediate assembly may be provided in various lengths to match different package specifications.

Here, the first busbar assembly may be composed of an injection-molded body into which a first busbar is inserted.

In addition, the first busbar may be L-shaped, and a L-shaped horizontal part may be positioned on a lower surface side of the first substrate.

In addition, the first busbar may have a perforation hole formed in the L-shaped horizontal part, so as to be coupled to the first substrate by inserting a bolt into one side of the perforation hole and fastening a nut to the other side thereof.

In this case, the first busbar may have the nut that is press-fitted into a lower inner side of the perforation hole.

In addition, N first busbars may be inserted horizontally side by side into the body of the first busbar assembly, and

N-1 shielding walls may be formed vertically to partition perforation holes of the N inserted first busbars.

Here, an insulating plate for electrical insulation may be inserted into an inside of each shielding wall.

According to another aspect of the present disclosure for solving the problems, the second busbar assembly of the present disclosure may be composed of an injection-molded body into which a second busbar is inserted.

In addition, projections for load support may be formed at a predetermined height in a length direction in a front surface of the body of the second busbar assembly, and a fixing protrusion inserted into a coupling hole of the second substrate may be formed extending downward from each projection.

In addition, N second busbars may be inserted horizontally side by side in the body of the second busbar assembly,

N projections for load support may be formed side by side at a predetermined height in a length direction on a front surface of the body where the N inserted second busbars are positioned, and N fixing protrusions inserted into coupling holes of the second substrate may be formed extending downward from the projections.

In addition, separately from the N fixing protrusions, a mis-assembly prevention protrusion for preventing mis-assembly may be formed extending from the body of the second busbar assembly.

Meanwhile, through-holes (352) may be formed in the body of the second busbar assembly so that a bottom surface of a recessed part (312b) of the second busbar (310) is positioned in a central part of each through-hole.

According to another aspect of the present disclosure for solving the problems, the busbar intermediate assembly of the present disclosure may be composed of an injection-molded body into which an intermediate busbar is inserted.

In addition, the first busbar, the second busbar, and the intermediate busbar may be composed of protruding parts and recessed parts so as to form bonding surfaces through surface contacts with each other.

In addition, each injection-molded body may be made of a thermally conductive polymer as a material.

According to one exemplary embodiment of the present disclosure, when busbars of different lengths are required due to the package design, a first busbar assembly and a second busbar assembly, which are coupled to a substrate side, are provided for common use, and only a busbar intermediate assembly having various lengths is replaced, thereby being able to accommodate product layouts with various specifications.

In particular, the exemplary embodiments of the present disclosure provide specifications for a busbar intermediate assembly with various lengths, so that a user may immediately apply busbars without the need to newly manufacture the busbars of specifications desired by the user and to go through testing and certification before introduction.

The coupling structure of a busbar intermediate assembly coupled to a first busbar assembly and a second busbar assembly may always be manufactured and managed uniformly, thereby preventing a problem of conventional length-adjustable busbar products in which the electrical characteristics of the busbar change as the contact surface changes with each change in length.

An electric vehicle may include the busbar module.

According to the present disclosure, a method of forming a variable length busbar module for a vehicle may include: coupling a first busbar assembly to a first substrate; coupling a second busbar assembly to a second substrate; and connecting the first busbar assembly and the second busbar assembly via a busbar intermediate assembly, wherein the busbar intermediate assembly is configured to be provided in various lengths.

### BRIEF DESCRIPTION OF THE DRAWINGS

FIG. 1 (RELATED ART) is a perspective view illustrating a power conversion device equipped with a conventional busbar and depicts a partial enlarged view of the busbar.

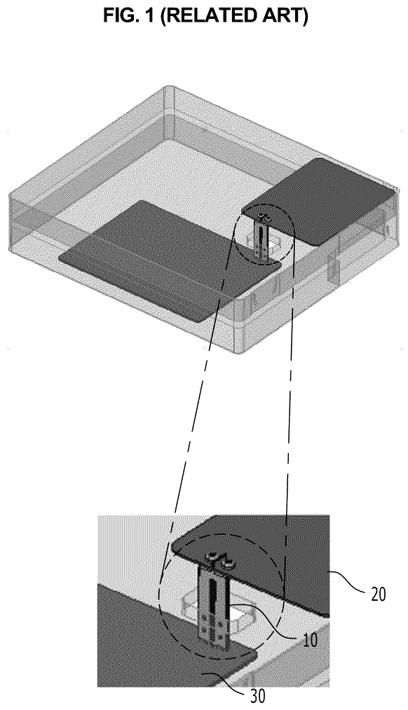

FIGS. 2A and 2B are installation views illustrating a busbar module having lengths different from each other according to one exemplary embodiment of the present disclosure.

FIG. 3 is an assembly view illustrating a variable length busbar module according to one exemplary embodiment of the present disclosure.

FIG. 4 is an exploded view illustrating the variable length busbar module according to one exemplary embodiment of the present disclosure.

FIGS. 5A and 5B are respectively a perspective view and a cross-sectional view illustrating a first busbar assembly of the variable length busbar module according to one exemplary embodiment of the present disclosure.

FIGS. 6A and 6B are respectively a perspective view and a front view of a second busbar assembly of the variable length busbar module according to one exemplary embodiment of the present disclosure.

FIG. 7 is a front view of a second busbar assembly of a variable length busbar module according to another exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter, preferred exemplary embodiments of the present disclosure will be described in detail with reference to the drawings.

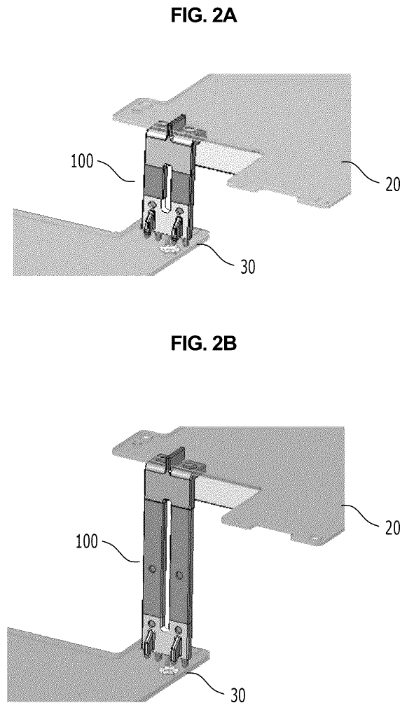

FIGS. 2A and 2B are installation views illustrating a busbar module 100 having lengths different from each other according to one exemplary embodiment of the present disclosure, showing a state in which the busbar module 100 of the present disclosure electrically connects a first substrate 20 and a second substrate 30 to each other, which are spaced apart from each other in the vertical direction.

FIG. 2A shows an installation example of the busbar module 100 when a distance between the first substrate 20 and the second substrate 30 is short, and FIG. 2B shows an installation example of the busbar module 100 when a distance between the first substrate 20 and the second substrate 30 is long.

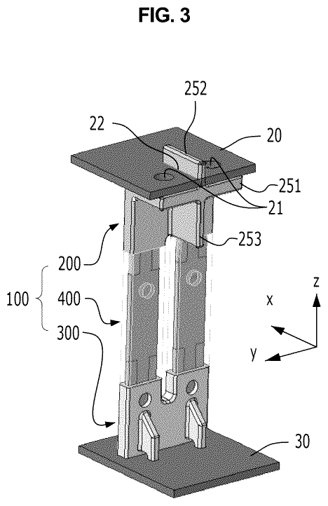

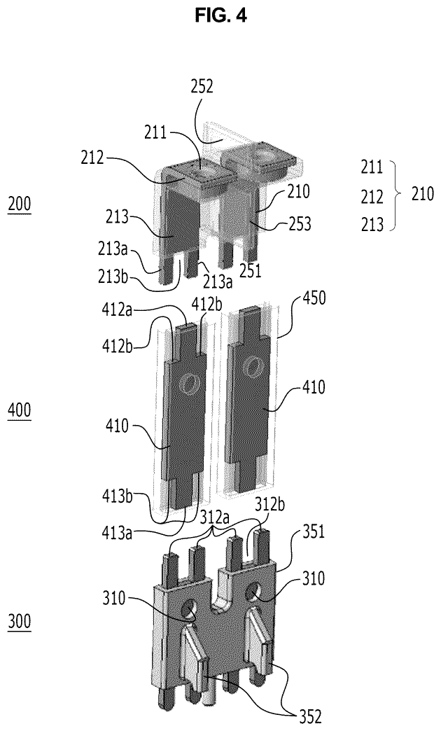

Next, FIG. 3 is an assembly view illustrating a variable length busbar module according to one exemplary embodiment of the present disclosure, and FIG. 4 is an exploded view illustrating the variable length busbar module according to one exemplary embodiment of the present disclosure.

Referring to FIGS. 3 and 4, the busbar module 100 with variable length according to one exemplary embodiment of the present disclosure includes: a first busbar assembly 200 coupled to a first substrate 20; a second busbar assembly 300 coupled to a second substrate 30; a busbar intermediate assembly 400 configured to connect the first busbar assembly 200 and the second busbar assembly 300 to each other, wherein the first busbar assembly 200 and the second busbar assembly 300 are used interchangeably regardless of package specifications, and the busbar intermediate assembly 400 is provided in various lengths to match different package specifications.

Here, the first busbar assembly 200, the second busbar assembly 300, and the busbar intermediate assembly 400 may be composed of injection-molded bodies into which the first busbar 210, the second busbar 310, and the intermediate busbar 410 are inserted, respectively.

For the sake of easy understanding, in the case of FIGS. 3 and 4, the body of the busbar intermediate assembly 400 is shown transparently and expressed only with outlines, and in the case of FIG. 4, the body of the first busbar assembly 200 is shown translucently. However, similar to the second busbar assembly 300, the busbar intermediate assembly 400 and the first busbar assembly 200 may be composed of respective injection-molded bodies into which an intermediate busbar 410 and a first busbar 210 are inserted, respectively.

In addition, the injection-molded bodies 250, 350, and 450 of the first busbar assembly 200, the second busbar assembly 300, and the busbar intermediate assembly 400 may be made of engineering plastic as a material.

In addition, these injection-molded bodies may preferably be made of a thermally conductive polymer as a material, and such thermally conductive polymer may be produced by adding the carbon-based particles or fibers having excellent electrical/thermal conductivity properties as an additive to existing plastic materials such as polypropylene (PP) and polystyrene (PS).

When the bodies of the first busbar assembly 200, second busbar assembly 300, and busbar intermediate assembly 400 are made of a material with good thermal conductivity, it is possible to improve the heat dissipation effect of these busbar assemblies for transmitting high power.

In addition, as shown in FIG. 4, protruding parts 213a formed on both sides of the lower end of L-shaped vertical part 213 of the first busbar 210 are fixedly fitted to recessed parts 412b formed on both sides of the upper part of the intermediate busbar 410, and a recessed part 213b formed in the lower end center of the vertical part 213 is fixedly fitted to a protruding part 412a formed in the center of the upper part of the intermediate busbar 410.

In addition, the protruding parts 213a formed on both sides of the lower end of the L-shaped vertical part 213 of the first busbar 210 may be formed to be exposed from a body 250 of the first busbar assembly 200, and recessed parts 412b formed on both sides of the upper part of the intermediate busbar 410 may be formed as grooves each having a predetermined depth from the upper surface of the busbar intermediate assembly 400 by a wall formed by the protruding part 412a formed in the center of the upper part of the intermediate busbar 410 and a body 450 of the intermediate busbar 410 that is injection-molded to surround the recessed parts 412b.

In addition, the recessed part 312b formed in the center of the upper part of the second busbar 310 is fixedly fitted to the protruding part 413a formed in the center of the lower part of the intermediate busbar 410, and the protruding parts 312a formed on both sides of the upper part of the second busbar 310 are fixedly fitted to the recessed parts 413b formed on both sides of the lower part of the intermediate busbar 410.

In addition, the protruding parts 312a formed on both sides of the upper part of the second busbar 310 are formed to be exposed from a body 350 of the second busbar assembly 300, and the recessed parts 413b formed on both sides of the lower part of the intermediate busbar 410 may be formed as respective grooves each having a predetermined depth from the lower surface of the busbar intermediate assembly 400 by a wall formed by the protruding part 412a formed in the center of the upper part of the intermediate busbar 410 and the body 450 of the intermediate busbar 410 that is injection-molded to surround the corresponding areas.

The above description is based on the configuration shown in FIG. 4, but as another exemplary embodiment of the present disclosure, when required, a protruding part may be formed in the center of the upper part of the second busbar 310, and a recessed part may be formed in the center of the lower part of the intermediate busbar 410, so that the second busbar assembly and the busbar intermediate assembly may also be coupled to each other.

In the cases of the exemplary embodiments as described above, the recessed part 213b formed in the center of the L-shaped vertical part 213 of the first busbar 210 may also be fitted into the protruding part formed in the center of the upper part of the second busbar 310, so as to respond to the shortest distance between the first substrate 20 and the second substrate 30.

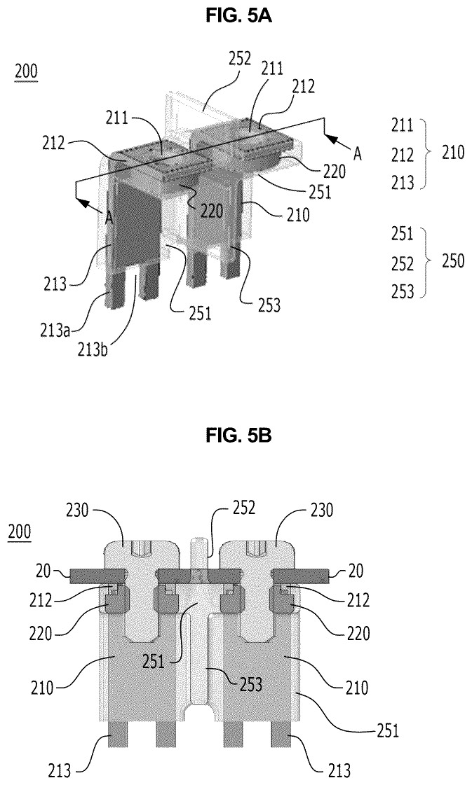

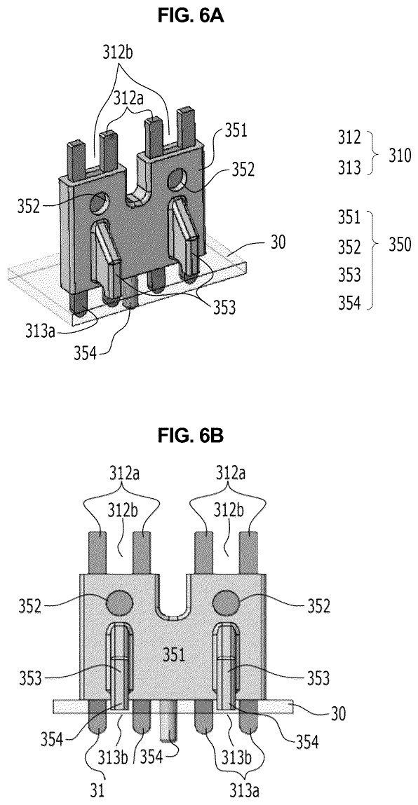

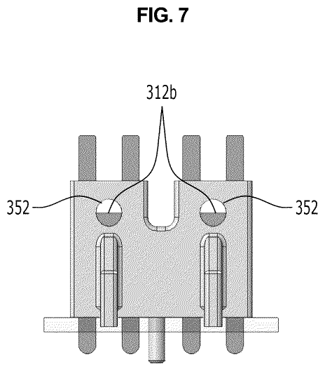

Next, FIGS. 5A and 5B are respectively a perspective view and a cross-sectional view illustrating a first busbar assembly of the variable length busbar module according to one exemplary embodiment of the present disclosure. FIGS. 6A and 6B are respectively a perspective view and a front view illustrating a second busbar assembly of the variable length busbar module according to one exemplary embodiment of the present disclosure. FIG. 7 is a front view of a second busbar assembly of a variable length busbar module according to another exemplary embodiment of the present disclosure.

Below, the configuration of the first busbar assembly 200 and the second busbar assembly 400 will be described in more detail with reference to FIGS. 5A to 7.

Referring to FIGS. 5A and 5B, according to the exemplary embodiments of the present disclosure, the first busbar assembly 200 as described above may be composed of the injection-molded body 250 into which the first busbar 210 is inserted. In this case, the first busbar 210 has an L-shape, and a horizontal part 212 of an L-shape may be positioned on a lower surface side of the first substrate 20.

In addition, here, the first busbar 210 has a perforation hole 211 formed in the L-shaped horizontal part 212, so as to be connected to the first substrate 20 by inserting a bolt 230 into one side of the perforation hole 211 and fastening a nut 220 into the other side thereof.

In addition, in the first busbar 210, the nut 220 may be press-fitted into the lower inner side of the perforation hole 211, or female screw threads may be formed on the inner circumferential surface the perforation hole 211.

According to such a configuration, while the first substrate 20 is placed on the horizontal part 212 side of the first busbar 210 inserted into the first busbar assembly 200 of the present disclosure, as shown in FIG. 5B, the first busbar assembly 200 may be firmly coupled to the first substrate 20 by combining the bolt 230 and the nut 220 or the bolt 230 and the female screw threads formed on the inner circumferential surface of the perforation hole 211.

In addition, as shown in the drawings of FIGS. 3 to 5B, two first busbars may be inserted horizontally side by side into the body of the first busbar assembly 200, and one shielding wall may be formed vertically to partition the perforation holes of the two inserted first busbars. Here, more specifically, an upper shielding wall 252 and a lower shielding wall 253 may be formed vertically in the shielding wall. Here, an insulating plate for electrical insulation may be inserted into each of the upper shielding wall 252 and lower shielding wall 253.

As shown in FIG. 3, the upper shielding wall 252 is fitted into and coupled to a cutout part 22 of the first substrate 20, so as to not only ensure a secure bond between the body 250 of the first busbar assembly 200 and the first substrate 20, but also shield a space between the heads of the screw-joined bolts 230 inserted into the coupling holes 21 of the first substrate 20, thereby preventing an unexpected short circuit, etc.

In addition, as shown in FIGS. 3 and 5B, the body 250 of the first busbar assembly 200 is formed in the L-shape, the upper shielding wall 252 is formed extending upward from the upper surface of the L-shape horizontal part 251, the lower shielding wall 253 is formed extending downward from a lower surface of the horizontal part 251, so that the shape formed by the horizontal part 251, the upper shielding wall 252, and the lower shielding wall 253 is preferably a +-shape when viewed from the front (i.e., toward a positive (+) x-axis direction), which is to increase the structural rigidity of the first busbar assembly 200 coupled to the first substrate.

Next, referring to FIGS. 6A and 6B, as described above, the second busbar assembly 300 may be composed of an injection-molded body into which the second busbar 310 is inserted. Projections 353 for load support may be formed at a predetermined height in the length direction on a front surface of the body of the second busbar assembly 300. A fixing protrusion 354 inserted into each coupling hole of the second substrate 30 may be formed extending downward from each projection 353.

In FIGS. 6A and 6B, each projection 353 formed toward a front direction (i.e., toward a negative (−) x-axis direction) of the body 350 of the second busbar assembly 300 is merely shown, but it is naturally that each projection may be formed toward a rear direction (i.e., toward the positive (+) x-axis direction) as required, or each projection may be formed in both the front direction (the negative (−) x-axis direction) and the rear direction (the positive (+) x-axis direction) from the body.

In addition, the I-shaped second busbar 310 may be inserted into the I-shaped vertical part 351 of the body 350 of the second busbar assembly 300. The protruding parts 312a and 313a and recessed parts 312b and 313b may be formed on the upper part 312 and lower part 313 of the second busbar 310 so as to be exposed from the upper surface and lower surface of the vertical part 351 of the body 350. In this case, the protruding part 313a of the lower part of the second busbar 310 may be inserted into a fixing hole made in the second substrate 30 and connected to a printed circuit provided in the second substrate by soldering.

In addition, as shown in the drawings of FIGS. 4, 6A, 6B, and 7, two second busbars 310 are inserted horizontally side by side in the body of the second busbar assembly 300, two projections for load support are formed side by side at a predetermined height in the length direction on the front surface of the body where the two inserted second busbars are positioned, and two fixing protrusions inserted into the coupling holes of the second substrate may be formed extending downward from the respective projections.

In addition, as shown in FIGS. 6A and 6B, in the body 350 of the second busbar assembly 300, a mis-assembly prevention protrusion 355 for preventing mis-assembly may be formed extending from the body separately from the two fixing protrusions 354.

In addition, as a yet another exemplary embodiment of the present disclosure, as shown in FIG. 7, through-holes 352 may be formed in a body 350 of a second busbar assembly 300 of the present disclosure so that the central part of a through-hole 352 is positioned on a bottom surface of a recessed part 312b of a second busbar 310. In this case, it is preferable that a protruding part 413a of an intermediate busbar 410 of a busbar intermediate assembly 400, the protruding part 413a being fitted into the recessed part 312b of the second busbar 310, is formed protruding outward from the lower surface of the intermediate busbar 410, so that the distal end surface of the protruding part 413a of the lower part of the intermediate busbar 410 is in contact with a bottom surface of the recessed part 312b of the upper part of the second busbar 310.

In addition, while the distal end surface of the protruding part 413a of the lower part of the intermediate busbar 410 and the bottom surface of the recessed part 312b of the upper part of the second busbar 310 are in contact with each other, a soldering tool can be inserted into the through-holes 352 to perform soldering, thereby maximally reducing the contact resistance between busbars.

In addition, it is naturally that the through-holes 352 may also be formed in the busbar intermediate assembly 400 or the first busbar assembly 200 as required.

As described above, FIGS. 4 to 7 only show that the two first busbars 210 and two second busbars 310 are inserted horizontally side by side into the bodies of the first busbar assembly 200 and the second busbar assembly 200, respectively. However, when required, N (N is an integer greater than or equal to 2) first busbars 210 and two second busbars 310 may be inserted horizontally side by side into the bodies of the first busbar assembly 200 and the second busbar assembly 200, respectively.

In addition, in this case, N-1 shielding plates configured to partition the perforation holes of the N inserted first busbars may be formed vertically in the body 250 of the first busbar assembly 200. N projections 353 for load support may be formed side by side at a predetermined height in the length direction on the front surface of the body where the N inserted second busbars are positioned in the body of the second busbar assembly 350. Fixing protrusions 354 to be inserted into coupling holes of the second substrate may be formed extending downward from these projections.

Next, referring to FIG. 4, as described above, the busbar intermediate assembly 400 may be composed of the injection-molded body having the intermediate busbar inserted therein, and as described above, the first busbar 210, the second busbar 310, and the intermediate busbar 410 may be composed of the protruding parts 213a, 312a, 412a, and 413a and the recessed parts 213b, 312b, 412b, and 413b, so as to form bonding surfaces through surface contacts with each other.

As described above, in the detailed description of the present disclosure, only specific exemplary embodiments thereof have been described. However, in the detailed description of the present disclosure, only specific exemplary embodiments thereof have been described. The present disclosure, however, should not be construed as being limited to only the specific modes referred to in the detailed description, but should be construed as rather covering modifications, equivalents, or alternatives within the idea and scope of the embodiment of the present disclosure as disclosed in the accompanying claims.

What is claimed is:

1. A variable length busbar module for a vehicle, comprising:
a first busbar assembly coupled to a first substrate;
a second busbar assembly coupled to a second substrate; and
a busbar intermediate assembly for connecting the first busbar assembly and the second busbar assembly to each other,
wherein the busbar intermediate assembly is configured to be provided in various lengths.

2. The busbar module of claim 1, wherein the first busbar assembly and the second busbar assembly are configured to be used interchangeably.

3. The busbar module of claim 1, wherein the first busbar assembly is composed of an injection-molded body, and a first busbar is configured to be inserted into the first busbar assembly.

4. The busbar assembly of claim 3, wherein the injection-molded body is made of a thermally conductive polymer.

5. The busbar module of claim 3, wherein the first busbar is L-shaped, and
an L-shaped horizontal part is positioned on a lower surface side of the first substrate.

6. The busbar module of claim 5, wherein the first busbar has a perforation hole formed in the L-shaped horizontal part, so as to be coupled to the first substrate by inserting a bolt into one side of the perforation hole and fastening a nut to the other side thereof.

7. The busbar module of claim 6, wherein the first busbar has the nut that is press-fitted into a lower inner side of the perforation hole.

8. The busbar module of claim 6, wherein N first busbars are inserted horizontally side by side into the body of the first busbar assembly, and
N-1 shielding walls are formed vertically to partition perforation holes of the N inserted first busbars.

9. The busbar module of claim 8, wherein an insulating plate for electrical insulation is inserted into an inside of each shielding wall.

10. The busbar module of claim 1, wherein the second busbar assembly is composed of an injection-molded body, and a second busbar is configured to be inserted into the second busbar assembly.

11. The busbar assembly of claim 10, wherein the injection-molded body is made of a thermally conductive polymer.

12. The busbar module of claim 10, wherein projections for load support are formed at a predetermined height in a length direction in a front surface of the body of the second busbar assembly, and
a fixing protrusion inserted into a coupling hole of the second substrate is formed extending downward from each projection.

13. The busbar module of claim 10, wherein N second busbars are inserted horizontally side by side in the body of the second busbar assembly,
N projections for load support are formed side by side at a predetermined height in a length direction on a front surface of the body where the N inserted second busbars are positioned, and
N fixing protrusions inserted into coupling holes of the second substrate are formed extending downward from the projections.

14. The busbar module of claim 13, wherein, separately from the N fixing protrusions, a mis-assembly prevention protrusion for preventing mis-assembly is formed extending from the body of the second busbar assembly.

15. The busbar module of claim 10, wherein through-holes are formed in the body of the second busbar assembly so that a bottom surface of a recessed part of the second busbar is positioned in a central part of each through-hole.

16. The busbar module of claim 1, wherein the busbar intermediate assembly is composed of an injection-molded body, and an intermediate busbar is configured to be inserted into the busbar intermediate assembly.

17. The busbar module of claim 16, wherein the injection-molded body is made of a thermally conductive polymer.

18. The busbar module of claim 1, further comprising a first busbar, a second busbar, and a intermediate busbar, wherein one or more of the first busbar, the second busbar, or the intermediate busbar are composed of protruding parts or recessed parts so as to form bonding surfaces through surface contacts with each other.

19. An electric vehicle comprising the busbar module of claim 1.

20. A method of forming a variable length busbar module for a vehicle, the method comprising:
coupling a first busbar assembly to a first substrate;
coupling a second busbar assembly to a second substrate; and
connecting the first busbar assembly and the second busbar assembly via a busbar intermediate assembly,
wherein the busbar intermediate assembly is configured to be provided in various lengths.
